(19) United States
(12) Patent Application Publication
(10) Pub. No.: US 2014/0354965 A1
(43) Pub. Date: Dec. 4, 2014

(54) IMMERSION LIQUID REPLENISHING APPARATUS, REPLENISHING METHOD, AND WAFER SCRIBING LINES INSPECTION MACHINE WITH IMMERSION LIQUID REPLENISHING APPARATUS

(71) Applicant: Yayatech Co., Ltd., Hsin-Chu (TW)

(72) Inventors: Ying-Cheng CHEN, Hsin-Chu (TW); Sheng-Feng Lin, Hsin-Chu (TW); Li-Chueh Chen, Hsin-Chu (TW); Yi-Chien Chen, Hsin-Chu (TW)

(73) Assignee: YAYATECH CO., LTD., Hsin-Chu (TW)

(21) Appl. No.: 13/948,860

(22) Filed: Jul. 23, 2013

(30) Foreign Application Priority Data
Jun. 4, 2013 (TW) 102119748

(51) Int. Cl. G03F 7/20

(52) U.S. Cl. CPC G03F 7/2041
USPC 355/30

(57) ABSTRACT

The present invention discloses an immersion liquid replenishing apparatus, a replenishing method, and a wafer scribing lines inspection machine with the immersion liquid replenishing apparatus. The immersion liquid replenishing apparatus inputs an immersion liquid from a first pipe of the cover and outputs the immersion liquid from a second pipe of the bottom of a reservoir. The replenishing method comprises the steps of providing an immersion liquid replenishing apparatus, feeding an immersion liquid, forming a film, and discharging the immersion liquid. The production and preparation of the apparatus and method of the invention is convenient and cheap. During a process of wafer scribing lines inspection, the wafer scribing lines inspection machine with the immersion liquid replenishing apparatus has enough immersion liquid to form the film and discharges excess immersion liquid.

### BACKGROUND OF THE INVENTION

1. Technical Field

The present invention relates to immersion liquid replenishing apparatuses, replenishing methods, and wafer scribing lines inspection machines each with an immersion liquid replenishing apparatus, and more particularly, to an immersion liquid replenishing apparatus with a first pipe, a second pipe, and a cylindrical storage chamber, a replenishing method, and a wafer scribing lines inspection machine with the immersion liquid replenishing apparatus.

2. Description of Related Art

As regards semiconductor manufacturing technology, overall results of wafer inspection are closely related with overall quality and image of semiconductor-related enterprises. However, inspection of wafer scribing lines is performed mostly on a wafer from above and thus is unable to detect any defect hidden on the lower surface of the wafer.

In attempt to inspect the defects on the lower surface of a wafer from below, most of inspection apparatuses encountered the problem of inspection images remain blurred, because the defects are concealed by a dicing tape adhered to the lower surface of the wafer. In view of this, the inventor of the present invention filed a Taiwan patent application 101147513 in year 2012 to put forth an immersion liquid which enables a light ray to penetrate the dicing tape better and thereby provide a structure and method for inspecting wafer scribing lines efficiently by the light ray which penetrates the dicing tape beneath the wafer from below, thereby rendering it easy to inspect the wafer scribing lines.

However, the immersion liquid for use with the aforesaid inspection method and structure decreases as the number of instances of inspection increases. Accordingly, it is imperative to devise an effective immersion liquid replenishing apparatus and replenishing method to thereby stabilize the image quality of inspection of wafer scribing lines and discharge excess immersion liquid.

### SUMMARY OF THE INVENTION

The present invention provides an immersion liquid replenishing apparatus, a replenishing method, and a wafer scribing lines inspection machine with an immersion liquid replenishing apparatus. The immersion liquid replenishing apparatus comprises a casing, a cover, a transparent plate, a film, and a cylindrical storage chamber, and is characterized in that; an immersion liquid is fed by means of a first pipe of the cover and discharged by means of a second pipe of a cylindrical storage chamber. The immersion liquid replenishing method comprises the steps of: providing an immersion liquid replenishing apparatus; feeding the immersion liquid; forming a film; and discharging the immersion liquid. According to the present invention, a wafer scribing lines inspection machine with the immersion liquid replenishing apparatus ensures that sufficient immersion liquid is available to form a film during a process of wafer scribing lines inspection and ensures that excess immersion liquid is discharged.

The present invention provides an immersion liquid replenishing apparatus for use in wafer scribing lines inspection. The immersion liquid replenishing apparatus comprises: a casing comprising an upper case portion, a lower case portion corresponding in position to the upper case portion, and a lateral case portion extending from an edge of the upper case portion to an edge of the lower case portion, wherein the upper case portion is provided centrally with a first through hole, and the lower case portion is provided centrally with a second through hole; a cover fixedly coupled to the casing and adapted to conceal the upper case portion, wherein a first gap is formed between the cover and the upper case portion, the cover having a third through hole and a first pipe coupled to a side of the cover, the third through hole being in connection with the first through hole, the third through hole being larger than the first through hole and adapted to conceal the first through hole, the first pipe having a first end aperture extending out of the cover and a second end aperture extending to the first gap; a transparent plate fixedly coupled to the upper case portion, adapted to conceal the first through hole, and being smaller than the third through hole, wherein a second gap is formed between the transparent plate and the third through hole; a film formed from an immersion liquid and on the transparent plate to conceal the transparent plate; and a cylindrical storage chamber fixed to the lateral case portion and having a recess portion and a second pipe, wherein the cover extends to an inner lateral side of the recess portion, whereas the second pipe penetrates a bottom side of the recess portion and extends out of the cylindrical storage chamber.

The present invention further provides a wafer scribing lines inspection machine with an immersion liquid replenishing apparatus. The wafer scribing lines inspection machine comprises: the aforesaid immersion liquid replenishing apparatus; and an object lens module fixed to and focusing adjustable with the wafer scribing lines inspection machine, adapted to pass through the second through hole of the immersion liquid replenishing apparatus, and spaced apart from the first through hole of the immersion liquid replenishing apparatus by a distance.

The present invention further provides an immersion liquid replenishing method for use in inspecting wafer scribing lines, comprising the steps of: providing an immersion liquid replenishing apparatus, wherein the immersion liquid replenishing apparatus comprises a casing, a cover, a cylindrical storage chamber, and a transparent plate, the casing comprising an upper case portion, a lower case portion, and a lateral case portion, the upper case portion being provided centrally with a first through hole, the lower case portion being provided centrally with a second through hole, the cover being fixedly coupled to the casing to conceal the upper case portion, wherein a first gap is formed between the cover and the upper case portion, the cover having a third through hole and a first pipe, the third through hole being in connection with the first through hole and being larger than the first through hole to conceal the first through hole, the first pipe comprising a first end aperture extending out of the cover and a second end aperture extending to the first gap, the cylindrical storage chamber being fixed to the lateral case portion and having a recess portion and a second pipe, the cover extending to an inner lateral side of the recess portion, the second pipe penetrating a bottom side of the recess portion and extending out of the cylindrical storage chamber, the transparent plate being fixedly coupled to the upper case portion and adapted to conceal the first through hole and being smaller than the third through hole, wherein a second gap is formed between the transparent plate and the third through hole; feeding an immersion liquid from the first pipe such that the immersion liquid flows onto the transparent plate via the second gap; forming a film from the immersion liquid and on the transparent plate to conceal the transparent plate; and discharging the immersion liquid, wherein the immersion liquid is conveyed from the upper case portion into the recess portion and then discharged from the cylindrical storage chamber via the second pipe.

Implementation of the present invention at least involves the following inventive steps:

1. manufacturing and installation can be carried out quickly, easily, and at low costs;

2. sufficient immersion liquid is available for use in a process of wafer scribing lines inspection to form a film; and

3. excess immersion liquid can be discharged smoothly without compromising the operation or the yield.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE SEVERAL VIEWS OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1 is a cross-sectional view of an immersion liquid replenishing apparatus according to the embodiment of the present invention;

FIG. 2 is a schematic cross-sectional view of an immersion liquid flowing within the immersion liquid replenishing apparatus according to the embodiment of the present invention;

FIG. 3 is a schematic cross-sectional view of a wafer scribing lines inspection machine with an immersion liquid replenishing apparatus, wherein a wafer under test is inspected through a dicing tape, according to the embodiment of the present invention;

FIG. 4 is a cross-sectional view of the wafer scribing lines inspection machine equipped with an immersion liquid replenishing apparatus and coupled to a base according to the embodiment of the present invention;

FIG. 5 is a flow chart of an immersion liquid replenishing method for use in inspecting wafer scribing lines according to the embodiment of the present invention; and

FIG. 6 is a schematic view of the direction of the flow of an immersion liquid according to the embodiment of the present invention.

### DETAILED DESCRIPTION OF THE EMBODIMENTS OF THE INVENTION

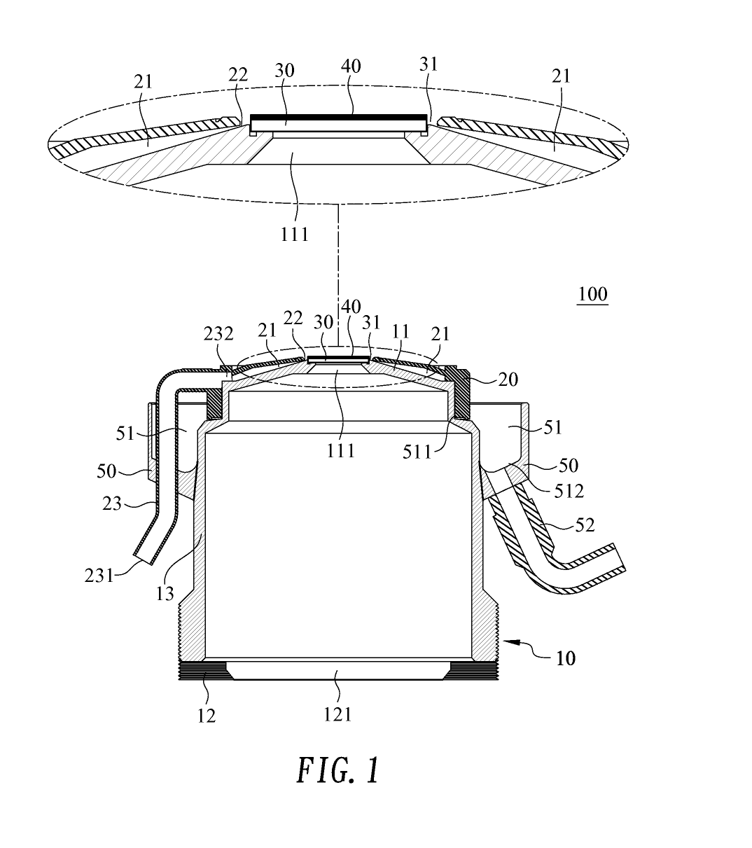

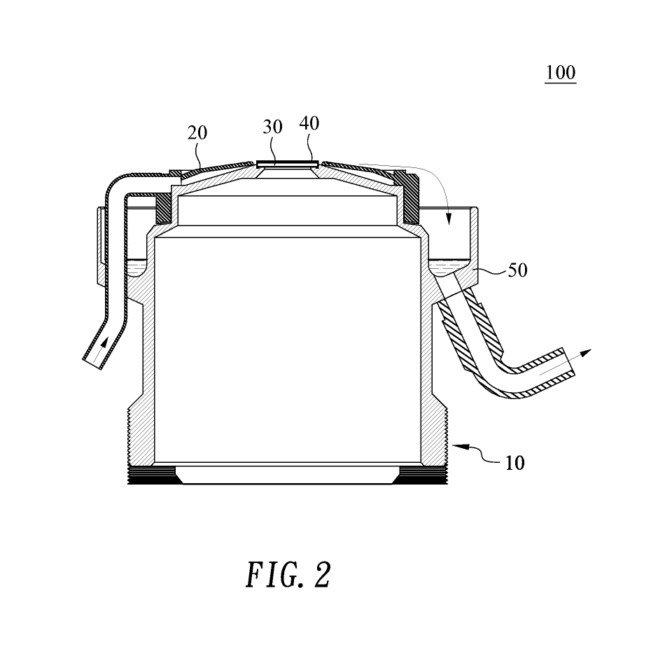

Referring to FIG. 1 and FIG. 2, an immersion liquid replenishing apparatus 100 of the present invention comprises a casing 10, a cover 20, a transparent plate 30, a film 40, and a cylindrical storage chamber 50.

Referring to FIG. 1 through FIG. 4, the casing 10 comprises: an upper case portion 11; a lower case portion 12 corresponding in position to the upper case portion 11; and a lateral case portion 13 extending from the outer edge of the upper case portion 11 to the outer edge of the lower case portion 12. The upper case portion 11 is provided centrally with a first through hole 111. The lower case portion 12 is provided centrally with a second through hole 121. The present invention is not restrictive of the shape of the casing 10. In this embodiment, the casing 10 has a barrel-shaped hollow core.

Referring to FIG. 1 through FIG. 4, the cover 20 is fixedly coupled to the casing 10 and adapted to conceal the upper case portion 11 of the casing 10. The cover 20 is not tightly attached to the top of the upper case portion 11, as a first gap 21 is disposed between the cover 20 and the top of the upper case portion 11. The cover 20 has a third through hole 22. A first pipe 23 is coupled to one side of the cover 20. The third through hole 22 is in connection with the first through hole 111. The third through hole 22 is larger than the first through hole 111 and conceals the first through hole 111. The first pipe 23 is coupled to one side of the cover 20 and has a first end aperture 231 extending out of the cover 20 and a second end aperture 232 extending to the first gap 21.

An immersion liquid, which originates from a source outside the immersion liquid replenishing apparatus 100, is fed to the first end aperture 231 of the first pipe 23 in a pressurized or guided manner and conveyed to the first gap 21 via the second end aperture 232 of the first pipe 23.

Referring to FIG. 1 through FIG. 4, the transparent plate 30 is fixedly coupled to the upper case portion 11 and adapted to conceal the first through hole 111 of the upper case portion 11. The transparent plate 30 is smaller than the third through hole 22 of the cover 20 and forms a second gap 31 together with the third through hole 22. The immersion liquid flows from the first gap 21 to the second gap 31 and conceals the transparent plate 30.

Referring to FIG. 1 through FIG. 4, the film 40 formed from the immersion liquid coated on the transparent plate 30. The transparent plate 30 is covered with the film 40 seamlessly.

Referring to FIG. 1 through FIG. 4, the cylindrical storage chamber 50 is fixed to the lateral case portion 13 and encloses a portion of the lateral case portion 13. The cylindrical storage chamber 50 has a recess portion 51 and a second pipe 52. The recess portion 51 has an inner lateral side 511. The position of the cylindrical storage chamber 50 relative to the cover 20 enables the cover 20 to extend to the inner lateral side 511 of the recess portion 51; hence, after the film 40 has been formed on the transparent plate 30, excess immersion liquid is guided by the cover 20 and discharged into the recess portion 51.

Referring to FIG. 1 through FIG. 4, as regards the cylindrical storage chamber 50, the second pipe 52 penetrates a bottom side 512 of the recess portion 51 and extends out of the cylindrical storage chamber 50. The immersion liquid in the recess portion 51 is discharged from the cylindrical storage chamber 50 by means of the second pipe 52.

Referring to FIG. 1 through FIG. 4, the immersion liquid, which originates from a source outside the immersion liquid replenishing apparatus 100, is conveyed to the transparent plate 30 via the first pipe 23 and forms the film 40 on the transparent plate 30. Excess immersion liquid is conveyed from the transparent plate 30 and the cover 20 into the recess portion 51 of the cylindrical storage chamber 50 and then discharged from the immersion liquid replenishing apparatus 100 via the second pipe 52. Hence, not only is the immersion liquid replenished, but excess immersion liquid is also discharged smoothly.

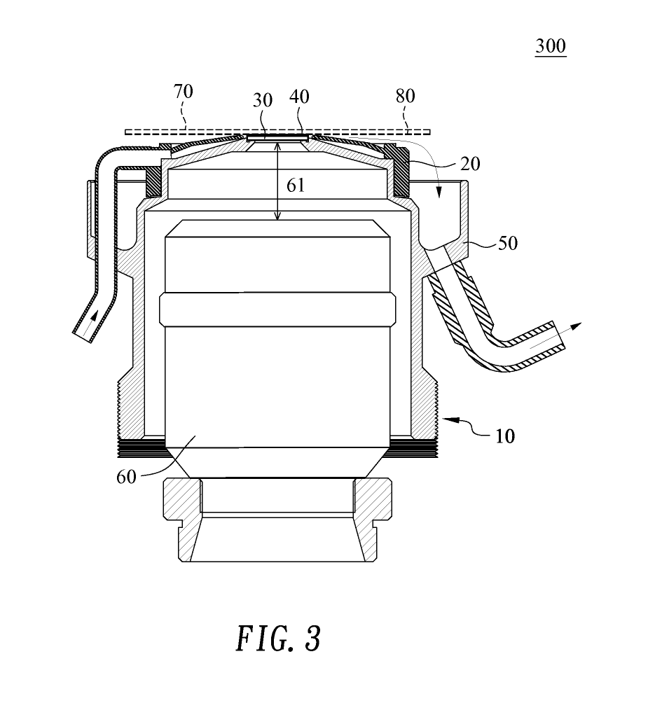

Referring to FIG. 3, in the embodiment of the present invention, a wafer scribing lines inspection machine 300 with the immersion liquid replenishing apparatus 100 comprises the immersion liquid replenishing apparatus 100 and an object lens module 60.

Referring to FIG. 3, the immersion liquid replenishing apparatus 100 of the wafer scribing lines inspection machine 300 is described above and thus is not described below again for the sake of brevity.

Referring to FIG. 3, the object lens module 60 is a microscope module or a microscope photographic module for conducting sophisticated inspection and capturing graphic data of inspection for later use. The object lens module 60 is fixed to and focusing adjustable with the wafer scribing lines inspection machine 300 and penetrates the second through hole 121 of the lower case portion 12. The object lens module 60 is spaced apart from the first through hole 111 by a distance 61 to facilitate the focusing adjustment or the automatic fine-tuning carried out by the object lens module 60 during a delicate inspection process.

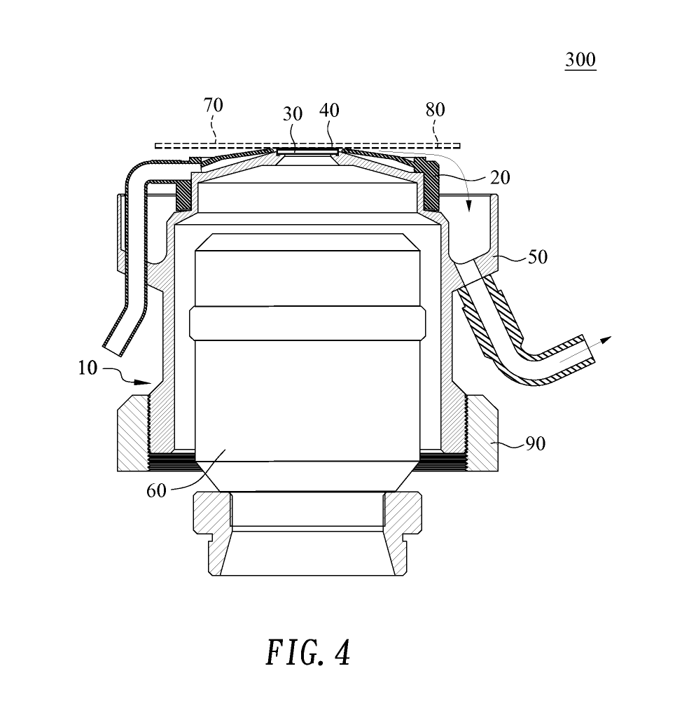

Referring to FIG. 4, the wafer scribing lines inspection machine 300 further comprises a base 90. The base 90 is fixed to the lateral case portion 13 of the immersion liquid replenishing apparatus 100 and enables the wafer scribing lines inspection machine 300 to be fixed in place. The base 90 is a portion of a large inspection machine and serves to fix the wafer scribing lines inspection machine 300 to the large inspection machine for inspection.

Referring to FIG. 3 and FIG. 4, a wafer under test 70 is placed on the film 40, and the film 40 is in tight contact with a dicing tape 80 of the wafer under test 70. Hence, after the film 40 on the wafer scribing lines inspection machine 300 has come into tight contact with the dicing tape 80 of the wafer under test 70, light rays penetrate the dicing tape 80 to thereby enable the wafer scribing lines inspection machine 300 to perform precise inspection and imaging on the wafer scribing lines of the wafer under test 70 despite of the dicing tape 80 therebetween.

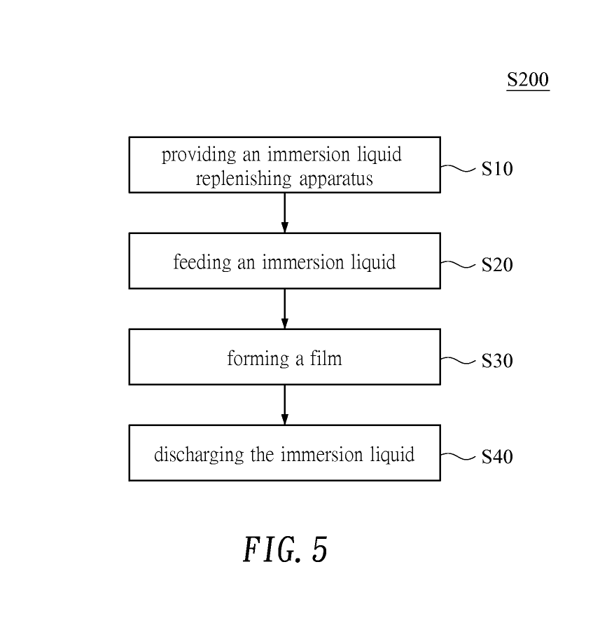

Referring to FIG. 5, there is shown a flow chart of an immersion liquid replenishing method (S200) according to the embodiment of the present invention. In this embodiment, the process flow of the immersion liquid replenishing method (S200) for use in inspecting wafer scribing lines comprises the steps of: providing an immersion liquid replenishing apparatus (step S10); feeding the immersion liquid (step S20); forming a film (step S30); and discharging the immersion liquid (step S40).

Referring to FIG. 5, in the step of providing an immersion liquid replenishing apparatus (step S10), the immersion liquid replenishing apparatus 100 described in the aforesaid embodiment and illustrated with FIG. 1 through FIG. 4 is provided.

Referring to FIG. 5, in the step of feeding the immersion liquid (step S20), the immersion liquid, which originates from a source outside the immersion liquid replenishing apparatus 100, is fed in a pressurized or guided manner via the first pipe 23 and then conveyed to the transparent plate 30 via the first gap 21 and the second gap 31 to conceal the transparent plate 30.

Referring to FIG. 5, in the step of forming a film (step S30), the immersion liquid conceals the transparent plate 30 seamlessly and forms the film 40, wherein the film 40 is in tight contact with the dicing tape 80 of the wafer under test 70, such that light rays penetrate the dicing tape 80.

Referring to FIG. 5, in the step of discharging the immersion liquid (step S40), excess immersion liquid is conveyed from the transparent plate 30 and the cover 20 into the recess portion 51 of the cylindrical storage chamber 50 of the immersion liquid replenishing apparatus 100 and then discharged smoothly from the immersion liquid replenishing apparatus 100 via the second pipe 52 in connection with the recess portion 51.

Referring to FIG. 5, in the embodiment of the present invention, the immersion liquid replenishing method (S200) is characterized in that: not only is the immersion liquid replenished and fed from the first pipe 23, but excess immersion liquid is also discharged via the second pipe 52 smoothly.

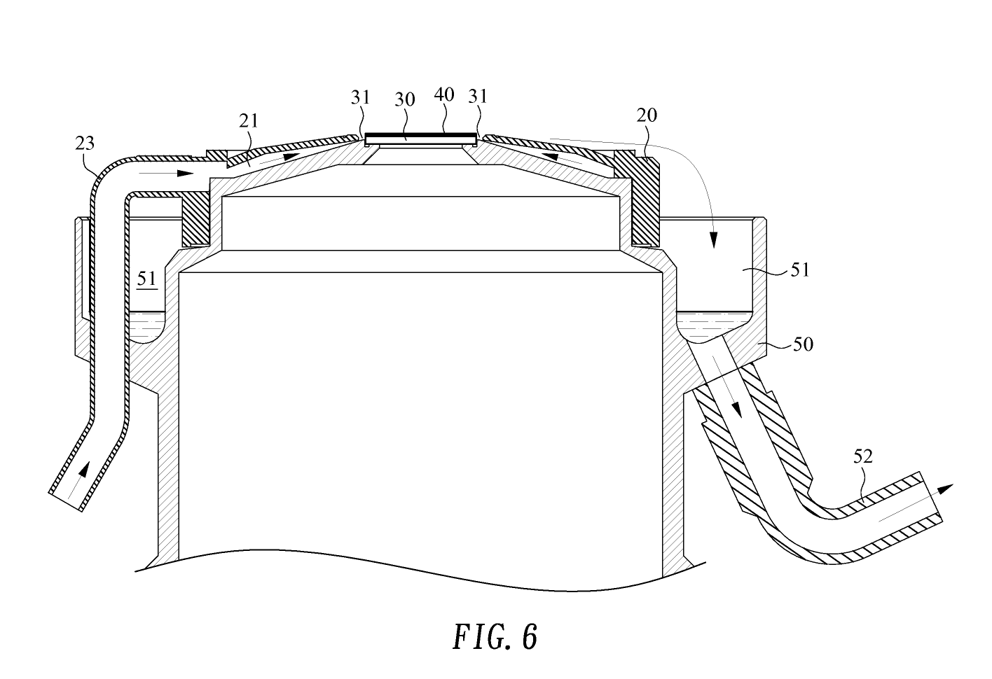

Referring to FIG. 6, as regards the immersion liquid replenishing apparatus 100 in the embodiment of the present invention, the wafer scribing lines inspection machine 300 with the immersion liquid replenishing apparatus 100 in the embodiment of the present invention, and the immersion liquid replenishing method (S200) in the embodiment of the present invention, not only is the immersion liquid fed from the first pipe 23, passed through the first gap 21 and the second gap 31, and adapted to form the film 40 on the transparent plate 30, but excess immersion liquid is also conveyed from above the cover 20 into the recess portion 51 of the cylindrical storage chamber 50 and then discharged via the second pipe 52 in connection with the recess portion 51.

In the aforesaid embodiments, the immersion liquid is transparent, and various immersion liquids of different refractive indices can be employed to meet different needs of inspection.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

What is claimed is:

1. An immersion liquid replenishing apparatus for use in wafer scribing lines inspection, the immersion liquid replenishing apparatus comprising:
a casing comprising an upper case portion, a lower case portion corresponding in position to the upper case portion, and a lateral case portion extending from an edge of the upper case portion to an edge of the lower case portion, wherein the upper case portion is provided centrally with a first through hole, and the lower case portion is provided centrally with a second through hole;
a cover fixedly coupled to the casing and adapted to conceal the upper case portion, wherein a first gap is formed between the cover and the upper case portion, the cover having a third through hole and a first pipe coupled to a side of the cover, the third through hole being in connection with the first through hole, the third through hole being larger than the first through hole and adapted to conceal the first through hole, the first pipe having a first end aperture extending out of the cover and a second end aperture extending to the first gap;
a transparent plate fixedly coupled to the upper case portion, adapted to conceal the first through hole, and being smaller than the third through hole, wherein a second gap is formed between the transparent plate and the third through hole;
a film formed from an immersion liquid and on the transparent plate to conceal the transparent plate; and
a cylindrical storage chamber fixed to the lateral case portion and having a recess portion and a second pipe, wherein the cover extends to an inner lateral side of the recess portion, whereas the second pipe penetrates a bottom side of the recess portion and extends out of the cylindrical storage chamber.

2. The immersion liquid replenishing apparatus of claim 1, wherein the immersion liquid enters the first end aperture and exits the second end aperture.

3. The immersion liquid replenishing apparatus of claim 1, wherein the immersion liquid flows from the transparent plate and a top of the cover into the recess portion.

4. The immersion liquid replenishing apparatus of claim 1, wherein the immersion liquid is discharged from the cylindrical storage chamber via the second pipe.

5. A wafer scribing lines inspection machine with an immersion liquid replenishing apparatus, comprising:
the immersion liquid replenishing apparatus, comprising:
a casing comprising an upper case portion, a lower case portion corresponding in position to the upper case portion, and a lateral case portion extending from an outer edge of the upper case portion to an outer edge of the lower case portion, wherein the upper case portion is provided centrally with a first through hole, and the lower case portion is provided centrally with a second through hole;
a cover fixedly coupled to the casing and adapted to conceal the upper case portion, wherein a first gap is formed between the cover and the upper case portion, the cover having a third through hole and a first pipe coupled to a side of the cover, the third through hole being in connection with the first through hole, being larger than the first through hole, and concealing the first through hole, the first pipe having a first end aperture extending out of the cover and a second end aperture extending to the first gap;
a transparent plate fixedly coupled to the upper case portion, adapted to conceal the first through hole, and being smaller than the third through hole, wherein a second gap is formed between the transparent plate and the third through hole;
a film formed from an immersion liquid and on the transparent plate to conceal the transparent plate; and
a cylindrical storage chamber fixed to the lateral case portion and having a recess portion and a second pipe, wherein the cover extends to an inner lateral side of the recess portion, whereas the second pipe penetrates a bottom side of the recess portion and extends out of the cylindrical storage chamber; and
an object lens module fixed to and focusing adjustable with the wafer scribing lines inspection machine, adapted to pass through the second through hole, and spaced apart from the first through hole by a distance.

6. The wafer scribing lines inspection machine of claim 5, further comprising a base is fixed to the lateral case portion and enables the wafer scribing lines inspection machine to be fixed in place.

7. The wafer scribing lines inspection machine of claim 5, wherein the film has thereon a wafer under test and is in tight contact with a dicing tape of the wafer under test.

8. An immersion liquid replenishing method for use in inspecting wafer scribing lines, comprising the steps of:
providing an immersion liquid replenishing apparatus, wherein the immersion liquid replenishing apparatus comprises a casing, a cover, a cylindrical storage chamber, and a transparent plate, the casing comprising an upper case portion, a lower case portion, and a lateral case portion; the upper case portion being provided centrally with a first through hole, the lower case portion being provided centrally with a second through hole, the cover being fixedly coupled to the casing to conceal the upper case portion, wherein a first gap is formed between the cover and the upper case portion, the cover having a third through hole and a first pipe, the third through hole being in connection with the first through hole and being larger than the first through hole to conceal the first through hole, the first pipe comprising a first end aperture extending out of the cover and a second end aperture extending to the first gap, the cylindrical storage chamber being fixed to the lateral case portion and having a recess portion and a second pipe, the cover extending to an inner lateral side of the recess portion, the second pipe penetrating a bottom side of the recess portion and extending out of the cylindrical storage chamber, the transparent plate being fixedly coupled to the upper case portion and adapted to conceal the first through hole and being smaller than the third through hole, wherein a second gap is formed between the transparent plate and the third through hole;
feeding an immersion liquid from the first pipe such that the immersion liquid flows onto the transparent plate via the second gap;
forming a film from the immersion liquid and on the transparent plate to conceal the transparent plate; and
discharging the immersion liquid, wherein the immersion liquid is conveyed from the upper case portion into the recess portion and then discharged from the cylindrical storage chamber via the second pipe.
